(19) United States
(12) Patent Application Publication
(10) Pub. No.: US 2010/0163091 A1
(43) Pub. Date: Jul. 1, 2010

(54) Composite material of complex alloy and generation method thereof, thermoelectric device and thermoelectric module

(75) Inventors: Yion-Ni Liu, Hsinchu City (TW); Chi-Cheng Hsu, Changhua County (TW); Ping-Jen Lee, Kaohsiung City (TW)

Correspondence Address: J C PATENTS, 4 VENTURE, SUITE 250, IRVINE, CA, 92618, US

(73) Assignee: Industrial Technology Research Institute, Hsinchu (TW)

(21) Appl. No.: 12/459,930

(22) Filed: Jul. 8, 2009

(30) Foreign Application Priority Data
Dec. 30, 2008 (TW) 97151407

(51) Int. Cl. H01L 35/12; H01B 1/04; H01B 1/02

(52) U.S. Cl. 136/236.1; 252/516; 252/519.51; 252/520.1; 252/520.21; 252/520.3; 252/520.4; 252/520.5; 252/521.1; 252/521.2; 252/521.4

(57) ABSTRACT

A composite material of complex alloy is provided and it is the Ceramic-Metal Composite based on a thermoelectric material filled with ceramic material. The composite material is represented by the following general formula (I).

A₁₋ₓBₓ (I)

In the general formula (I), 0.05≦X≦0.2; A represents a Half-Heusler thermoelectric material and its proportional composition is represented with the following formula (II).

(Tiₐ₁Zr_{b1}Hf_{c1})_{1-y-z}Ni_{y} Sn_{z} (II)

In the general formula (II), 0<a1<1, 0<b1<1, 0<c1<1, a1+b1+c1=1, 0.25≦y≦0.35, and 0.25≦z≦0.35; B represents at least one element selected from a group of C, O, and N.

### CROSS-REFERENCE TO RELATED APPLICATION

This application claims the priority benefit of Taiwan application serial no. 97151407, filed on Dec. 30, 2008. The entirety of the above-mentioned patent application is hereby incorporated by reference herein and made a part of this specification.

### BACKGROUND OF THE INVENTION

1. Field of the Invention

The present invention relates to a composite material of complex alloy and a generation method thereof, a thermoelectric device, and a thermoelectric module.

2. Description of Related Art

In Feb. 16, 2005, the Kyoto Protocol is announced as officially effective. All the subscribed countries (with a total of 141 countries) participated in the meeting agreed to reduce the collective emission of greenhouse gases, which includes six kinds of greenhouse gases such as carbon dioxide, by 5.2% (compared to the year 1990) in the major industrialized countries from 2008 to 2012. According to the relevant data proclaimed by New Carbon Finance in April, 2007, the global carbon fund has raised 4.7 billion USD in the last six months and rapidly increased their properties by almost 70%. Thus, from the activities of low-carbon technologies and anti-global warming, it is clear that a trend of green environmental protection has slowly evolved. On the other hand, countries with industrial pollutions have been signing agreements with developing countries or third-world countries to exchange for greenhouse gas emissions rights with money. In addition, the developments of environmental protection technologies, such as related projects in wind power, tidal energy, biomass energy, and solar power energy generation are progressed actively. This also illustrates the policy trend of the current petrochemical industry and the development and aspiration of green energy in the future.

Currently, most of the daily apparatuses (i.e. vehicles, home appliances, etc) generate waste heat during use. For example, the heat efficiency of the internal combustion engine system in an automobile merely reaches 15% or lower with most of the power been converted to waste heat, which is exhausted to the atmosphere in various ways. Not only cars, but also the home air-conditioning and refrigerating system, etc, have lots of waste heat. As the effective use of regeneration energy can retard global warming, and the regeneration energy has now become one of the most important tasks in the world.

The module which is composed by thermoelectric material can directly convert between thermal energy and electrical energy. Moreover, the thermoelectric module does not require moving parts, and is reliable and quiet. The thermoelectric module does not need combustion, which makes it environment friendly. Additionally, the thermoelectric module is light, compact, and portable. Consequently, the thermoelectric material has gradually become one of the targets in developing green energy technology.

Recently, with the progression of nano-technology, some thermoelectric materials can obtain a higher thermoelectric figure of merit (ZT). For example, the ZT value of Bi₂Te₃ superlattice can reach above 1.0; the ZT value of AgPbₘSbTe₂₊ₘ alloy, which was utilized by Michigan University in 2004, is 2.4; and the ZT value of the molecular beam epitaxy superlattice quantum dots, which was used by MIT in 2006, can reach 3.5. In detail, the method of suppressing the phonon (lattice vibration) transmission is applied to reduce the thermal conductivity with the heter-layer structure. However, the materials all required the superlattice/quantum dots thin film processing techniques which is expensive, are not practical to convert energy in large scales in mass production. In addition, energy conversion of large areas is mainly focused in thermoelectric bulks. In order to enhance the thermoelectric property, the process is usually complicated and costly, but the increase in ZT value is limited.

### SUMMARY OF THE INVENTION

The present invention provides a composite material of complex alloy, in which the thermoelectric ZT value can be increased by reducing thermal conductivity.

The present invention further provides a thermoelectric device for enhancing the thermoelectric converting efficiency.

The present invention further provides a thermoelectric module for enhancing the thermoelectric property and the thermoelectric converting efficiency to expand the applications in the industry and benefit in waste heat recycling power generation.

The present invention further provides a method of generating a composite material of complex alloy, in which a composite material with a good thermoelectric converting efficiency can be generated while reducing the generation cost.

The present invention provides a composite material of complex alloy, where the composite material is a Ceramic-Metal Composite based on a thermoelectric material filled with a ceramic material. The composite material is represented by the following general formula (I).

A₁₋ₓBₓ (I)

In the general formula (I), 0.05≦X≦0.2; A represents a thermoelectric material and its proportional composition is represented with the following formula (II).

(Tiₐ₁Zr_{b1}Hf_{c1})_{1-y-z}Ni_{y} Sn_{z} (II)

In the general formula (II), 0<a1<1, 0<b1<1, 0<c1<1, a1+b1+c1=1, 0.25≦y≦0.35, and 0.25≦z≦0.35. In the general formula (I), B represents at least one element selected from a group of C, O, and N.

The present invention further provides a thermoelectric device, which includes an N-type semiconductor and/or a P-type semiconductor. Here, the material of the N-type semiconductor and/or the P-type semiconductor is the above-mentioned composite material of complex alloy.

The present invention further provides a thermoelectric module, which includes a plurality of N-type semiconductors and a plurality of P-type semiconductors. Herein, the N-type and the P-type semiconductors are alternately connected in series and coupled through the electrodes therein. Also, the material of the N-type semiconductors and/or the P-type semiconductors is the aforementioned composite material of complex alloy.

The present invention further provides a method of generating the aforementioned composite material of complex alloy. The method includes, firstly, cleaning the metal raw materials with a purity higher than 99%. The metal raw materials include Ti, Zr, Hf, Ni, and Sn. Next, a melting process is performed on the metal raw materials and a raw material of heter-material at high temperature so as to form a thermoelectric composite material having a heter-material.

In light of the foregoing, by combining the Half-Heusler thermoelectric material and the heter-material formed therein, the present invention effectively reduces the phonon thermal conductivity (K_{L}) and thereby reduces the thermal conductivity so as to enhance the thermoelectric ZT value.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a thermoelectric device according to an embodiment of the present invention.

FIG. 2 is a schematic cross-sectional view of a thermoelectric module according to another embodiment of the present invention.

FIG. 3 is a flow diagram of generating the aforementioned composite material of complex alloy according to another embodiment of the present invention.

FIG. 4 is a flow diagram of generating the aforementioned composite material of complex alloy according to another embodiment of the present invention.

FIG. 5 is a SEM diagram of the composite material of complex alloy obtained from the experiment of the present invention.

FIG. 6 is a SEM diagram of the heter-material in the composite material of complex alloy obtained from the experiment of the present invention.

### DESCRIPTION OF EMBODIMENTS

The composite material of complex alloy in the present invention is the Ceramic-Metal Composite based on a thermoelectric material filled with ceramic material. The composite material of complex alloy is represented with the following general formula (I).

A₁₋ₓBₓ (I)

In the general formula (I), 0.05≦X≦0.2; A represents a Half-Heusler (“HH” thereafter) thermoelectric material; B represents at least one element selected from a group of C, O, and N.

The proportional composition of A is represented with the following formula (II).

(Tiₐ₁Zr_{b1}Hf_{c1})_{1-y-z}Ni_{y} Sn_{z} (II)

In the general formula (II), 0<a1<1, 0<b1<1, 0<c1<1, a1+b1+c1=1, 0.25≦y≦0.35, and 0.25≦z≦0.35.

In an embodiment of the present invention, A in the formula (I) is an HH thermoelectric material. It has been indicated in relevant research studies that the use of HH alloy techniques can reduce the high thermal conductivity of traditional metal materials and maintain electrical conductivity.

For instance, in the formula (I), A can be an alloy with a crystal structure of the MgAgAs type. In the face-centered cubic (FCC) structure of MgAgAs, the HH alloy has the following properties: 1. a semiconductor behaves; 2. the number of valence electrons periphery on the sp-hybrid orbital at 8 or spd-hybrid orbital at 18 in each compound structure that will change the status of the metal material; 3. “heavy fermion” properties which come from the fact that the conduction electrons in these metallic compounds behave as if they had an effective mass up to 1000 times the free-electron mass in the HH alloy.

It is challenging to maintain both the power factor and the thermal conductivity of thermoelectric materials. The present invention regulates the electrons and the phonons separately, and obtains a good power factor by regulating the number of valence electrons in every HH chemical formula to adjust the semiconductor characteristic thereof. Next, this formula is utilized as the main material system to replace a portion of light atoms with heavy atoms which have similar electronic structures. Thus, the thermal conductivity can be greatly reduced without reducing the power factor so as to acquire a higher ZT value.

In the formula (I), A is initially from a TiNiSn complex alloy of an HH alloy and includes a crystal structure of alternately arranged FCCs of Ti, Ni, and Sn. Moreover, the parts of heavy atoms and large atoms at the Ti, Ni, and Sn of the TiNiSn complex alloy are substituted, such that the masses of the light and heavy atoms on the atomic arrangement are greatly fluctuated. Consequently, the transmission speed of phonon will be greatly reduced to lower the thermal conductivity effectively. Moreover, the charge carrier is regulated through doping in the TiNiSn complex alloy, so that the number of valence electrons periphery in this formula (I) equals to 18. The design of the lattice atoms is as the following.
1. The heavy atoms that can effectively replace a part of the positions of Ti (atomic mass=47.9) include Zr (atomic mass=91.22) or Hf (atomic mass=178.49). Here, the heavy and light atoms can reach a mass ratio fluctuation of 3.73 times, as shown in formula (II). Moreover, a part of Ti, Zr, and Hf in the formula (II) can be replaced by at least one element selected from a group consisting of Y, Nb, Ta, Sc, W, V, La, and Ce.
2. The heavy atoms that can effectively replace a part of the positions of Ni (atomic mass=58.71) is selected from the Pd (atomic mass=106.4) or Pt (atomic mass=195.09), or Co (atomic mass=58.9332), which is in the neighboring row and has one less valence electron than that of Ni, or Ag. Here, the heavy and light atoms can reach a mass ratio fluctuation of 3.73 times.
3. As for Sn, a part of Sn can be replaced by at least one element selected from Sb, Te, Si, Pb, and Ge. For example, Sn may be replaced by Sb (atomic mass=121.75), which is in the neighboring row and has one more valence electron than that of Sn.

The raw material of B in the formula (I) can be at least one material selected from oxide, nitride, carbide, and a combination thereof. For instance, if the raw material of B is an oxide, then the material can be aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide. The more preferable material includes zirconium oxide, silicon oxide, titanium oxide, niobium oxide, hafnium oxide, yttrium oxide, wolfram oxide, cerium oxide, antimony oxide and lanthanum oxide. If the raw material of B is a nitride, then the material can be boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride. The more preferable material includes boron nitride, indium nitride, zirconium nitride, aluminum nitride, silicon nitride, titanium nitride, niobium nitride, hafnium nitride, wolfram nitride, or scandium nitride. If the raw material of B is a carbide, then the material can be boron carbide, zirconium carbide, titanium carbide, silicon carbide, niobium carbide, hafnium carbide, wolfram carbide, molybdenum carbide, chromium carbide, or vanadium carbide. The more preferable material includes boron carbide, zirconium carbide, titanium carbide, silicon carbide, niobium carbide, hafnium carbide, or wolfram carbide.

The solid thermal conductivity (K) can be divided into the transmission contribution of electron and lattice: K=Ke+K_{L}. Herein, the phonon thermal conductivity K_{L} is the major thermal source in the application of thermoelectric material. Moreover, the reduction in thermal conductivity can effectively increase the thermoelectric figure of merit ZT. Theoretically, an increase in phonon dispersion, which results by using phonons and impurities (i.e. dislocations, grain boundaries, interfaces, stress fields, vacancies, composition differences, mass differences), can effectively reduce K_{L}. Therefore, the present invention forms a compound with low thermal conductivity in the base material of thermoelectric material by using a method of forming a composite material to reduce the overall thermal conductivity.

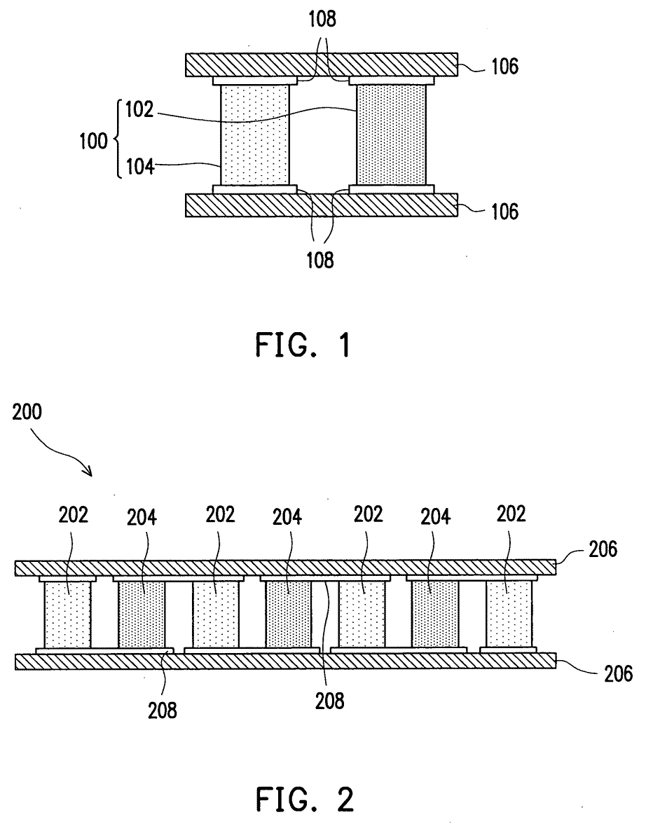

FIG. 1 is a schematic cross-sectional view of a thermoelectric device according to an embodiment of the present invention. Referring to FIG. 1, a thermoelectric device 100 includes an N-type semiconductor 102 and a P-type semiconductor 104. Usually, the thermoelectric device 100 further includes a substrate 106 and an electrode 108. In the thermoelectric device 100 of FIG. 1, the material of the N-type semiconductor 102 and/or the P-type semiconductor and 104 is the composite material of complex alloy aforementioned in the present invention. In alternative embodiment, the thermoelectric device 100 may include neither the N-type semiconductor 102 or the P-type semiconductor 104.

FIG. 2 is a schematic cross-sectional view of a thermoelectric module according to another embodiment of the present invention. Referring to FIG. 2, the thermoelectric module 200 includes more than one N-type semiconductors 202, more than one P-type semiconductors 204. Here, the N-type semiconductors 202 and the P-type semiconductors 204 that are disposed between a pair of substrates 206 are alternately connected in series and coupled through electrodes 208. In the thermoelectric module 200 of FIG. 2, the material of the N-type semiconductors 202 and/or the P-type semiconductors 204 is the composite material of complex alloy aforementioned in the present invention. Furthermore, the thermoelectric module 200 can be used as a refrigeration module.

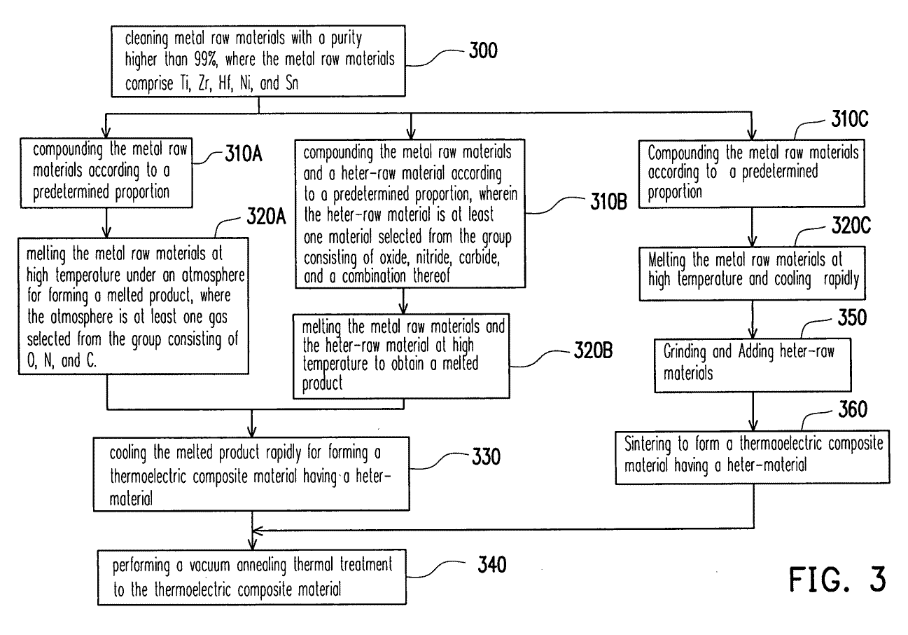

FIG. 3 is a flow diagram of generating the aforementioned composite material of complex alloy according to another embodiment of the present invention.

Referring to FIG. 3, step 300 is firstly performed for cleaning the metal raw materials with a purity higher than 99%. The metal raw materials include Ti, Zr, Hf, Ni, and Sn. Moreover, a part of Ti, Zr, and Hf in the metal raw materials can be replaced by at least one element selected from a group consisting of Nb, Sc, Y, W, Ta, V, La, and Ce. A part of Ni in the metal raw materials can be replaced by at least one element selected from a group consisting of Pd, Pt, Co, and Ag. A part of Sn in the metal material can be replaced by at least one element selected from a group consisting of Sb, Te, Si, Pb, and Ge.

Thereafter, there are several ways to produce a thermoelectric composite material having a heter-material.

In step 310A or 310C, the compounding of the metal raw materials aforementioned according to a predetermined proportion is performed.

In step 310B, other than compounding the metal material according to the predetermined proportion, a heter-raw material has to be added based on a predetermined proportion. The heter-raw material is at least one material selected from a material group consisting of oxide, nitride, carbide, and a combination thereof. The oxide in the heter-raw material is, for example, aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide. The nitride in the heter-raw material is, for example, boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride. The carbide in the heter-raw material is, for instance, boron carbide, zirconium carbide, titanium carbide, silicon carbide, niobium carbide, hafnium carbide, wolfram carbide, molybdenum carbide, chromium carbide, or vanadium carbide.

In step 320A, the metal raw materials mentioned above are melted at high temperature under an atmosphere of heter-materials to form a melted product. Here, the atmosphere is at least one gas selected from a gas group consisting of oxygen (O), nitrogen (N), and carbon (C); for example, oxygen gas or nitrogen gas.

In step 320B, the metal raw materials and the heter-materials are melted at high temperature for obtaining the melted product. In step 320C, the metal raw materials are melted at high temperature to form a melted product and the melted product is cooled rapidly. In steps 320A, 320B and 320C, the high temperature for melting is higher than 1200° C., for example.

Afterward, step 330 is performed for cooling the melted product rapidly to form the thermoelectric composite material having the heter-material. Here, the cooling speed of rapidly cooling the melted product is greater than 100° C./sec.

Thereafter, step 340 can be proceeded for performing vacuum annealing thermal treatment to the thermoelectric composite material. The temperature of the treatment has a range of 750° C.-1200° C., for example, to perform homogenization and impurity phase removal.

In addition, the thermoelectric composite material having the heter-material can be molded, sintered and ground between step 330 and step 340. The molding and sintering processes are methods such as the injection molding, the hot pressing or the hot isotropic pressing, and the spark plasma sintering.

In step 350, the heter-raw materials are added while the melted product is ground to form a mixture.

In step 360, the mixture is sintered at a temperature higher than 800° C.

In the present embodiment, the heter-material in the thermoelectric composite material formed is selected from, for example, at least one material from the material group consisting of oxide, nitride, carbide, and a combination thereof. Here, the oxide in the heter-material is, for example, aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide. The nitride in the heter-material is, for example, boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride. The carbide in the heter-material is, for instance, boron carbide, zirconium carbide, titanium carbide, silicon carbide, niobium carbide, hafnium carbide, wolfram carbide, molybdenum carbide, chromium carbide, or vanadium carbide.

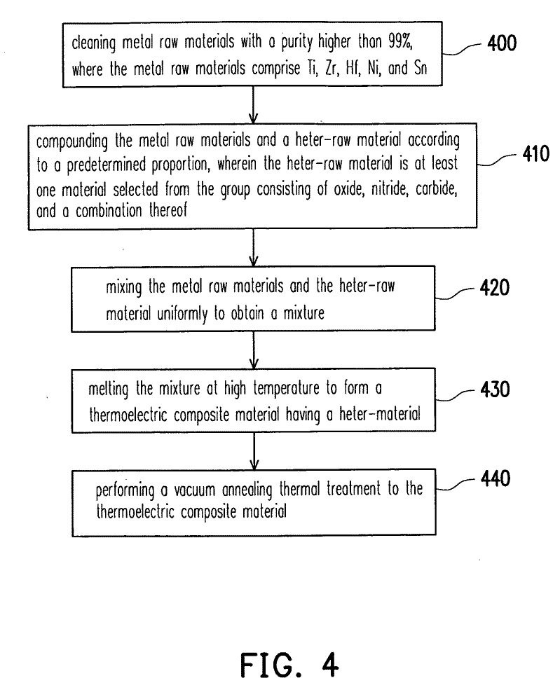

Other than the steps in FIG. 3, the composite material of complex alloy in the present invention can also be produced with the generation method in FIG. 4.

Referring to FIG. 4, step 400 is firstly performed for cleaning the metal raw materials with a purity higher than 99%. The metal raw materials include Ti, Zr, Hf, Ni, and Sn. Moreover, a part of Ti, Zr, and Hf in the metal raw materials can be replaced by at least one element selected from a group consisting of Nb, Sc, Y, W, Ta, V, La, and Ce. A part of Ni in the metal raw materials can be replaced by at least one element selected from a group consisting of Pd, Pt, Co, and Ag. A part of Sn in the metal raw materials can be replaced by at least one element selected from a group consisting of Sb, Te, Si, Pb, and Ge.

Next, step 410 is performed for compounding the metal raw materials and a heter-raw material according to a predetermined proportion. The heter-raw material is at least one material selected from a material group consisting of oxide, nitride, carbide, and a combination thereof. The oxide in the heter-raw material is, for example, aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide. The nitride in the heter-raw material is, for example, boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride. The carbide in the heter-raw material is, for instance, boron carbide, zirconium carbide, titanium carbide, silicon carbide, niobium carbide, hafnium carbide, wolfram carbide, molybdenum carbide, chromium carbide, or vanadium carbide.

Afterward, step 402 is proceeded for mixing the metal raw materials and the heter-raw material uniformly to obtain a mixture. The method of mixing the metal raw material and the heter-raw material uniformly includes ball milling, stirring, or roll mixing.

Afterward, step 430 is performed for melting the mixture at high temperature to form a thermoelectric composite material having a heter-material. The high temperature for melting is, for example, higher than 1200° C. The heter-material in the thermoelectric composite material formed is selected from, for example, at least one material from the material group consisting of oxide, nitride, carbide, and a combination thereof. Here, the oxide in the heter-raw material is, for example, aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide. The nitride in the heter-raw material is, for example, boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride. The carbide in the heter-raw material is, for instance, boron carbide, zirconium carbide, titanium carbide, silicon carbide, niobium carbide, hafnium carbide, wolfram carbide, molybdenum carbide, chromium carbide, or vanadium carbide.

Finally, step 440 can be proceeded for performing an vacuum annealing thermal treatment to the thermoelectric composite material. In addition, the vacuum annealing thermal treatment is usually performed in an apparatus different from that in the step 430. The function of this step is similar to step 340 in FIG. 3. The temperatures can both be between 750° C.-1200° C. to perform homogenization and impurity phase removal.

In addition, the thermoelectric composite material having the heter-material can be molded, sintered and ground between step 430 and step 440. The molding and sintering processes are methods such as the injection molding, the hot pressing and the hot isotropic pressing, and the spark plasma sintering.

In the present invention, it is possible to produce the heter-material by the addition of the heter-raw materials or by the reaction between metal raw materials v.s heter-raw materials, or by the reaction the metal raw materials in the active atmosphere.

An experiment is listed below to prove the effect of the present invention.

### Experiment

The steps below are followed accordingly to perform the experiment.
1. Clean the metal raw materials required: elements Ti, Zr, Hf, Ni, Sn, etc, where the purity of each element is higher than 99.99%.
2. Compound the proportion of each element and component for generating the composite material of complex alloy {(Ti_{0.46}Zr_{0.3}Hf_{0.24})_{0.37}Ni_{0.3}Sn_{0.33}}_{0.885}O_{0.115}.
3. Perform the melting at high temperature: a high temperature furnace, such as the melting furnace, the high frequency furnace, the electrical induction furnace, the electric ARC furnace, or the resistance furnace, is applied. The compounded metal material and the heter-raw material ZrO₂ added are disposed in the crucible or the copper chill box to be melted, and are then heated to a temperature higher than 1200° C. to obtain the melted product.
4. After the materials have melted evenly, the liquid cooling method (liquid nitrogen method) is utilized to pass through the interior of the copper chill box to cool the melted product with a cooling speed >100° C./sec. This copper is a designed thermal exchanger model. Here, the internal working fluid is water, ethanol, or liquid nitrogen. The method is to control the nucleation on the liquid solid interface when using the melted metal raw materials, and thereby inhibits the granule growth and reduces the component segregation. Therefore, a thermoelectric composite material having an additive of a heter-material is formed.
5. The thermoelectric composite material is sealed with a quartz tube, and is performed with the vacuum annealing thermal treatment in the annealing furnace. The temperature therein is 750° C.-1200° C.

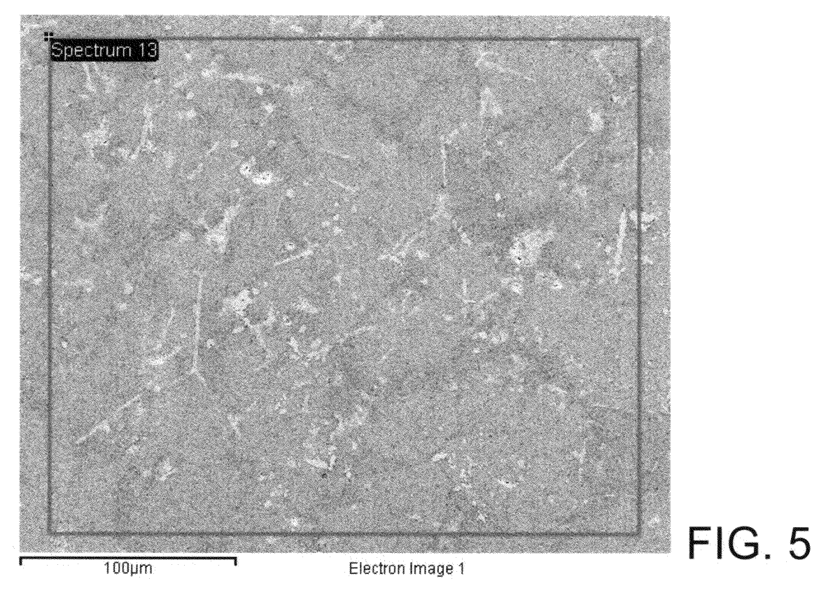

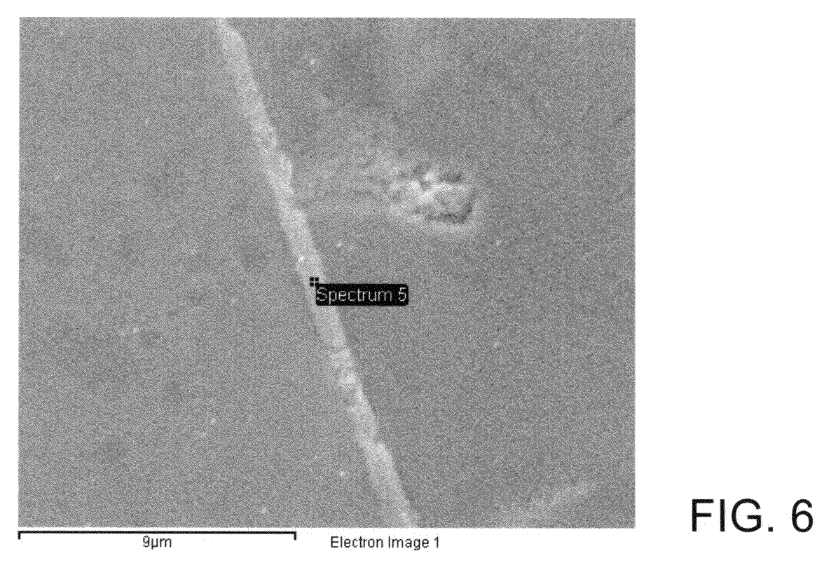

The composite material of complex alloy generated with the foregoing steps is illustrated in FIG. 5, which shows a SEM diagram of the composite material of complex alloy that is obtained from the experiment. In FIG. 5, the evenly distributed heter-material is present in the base material of thermoelectric material (the white or lighter parts of the diagram).

The composition elements and the components thereof of the composite material of complex alloy obtained using the EDS analysis is illustrated in Table 1.

TABLE 1

| Element | Weight % | Atomic % |
|---|---|---|
| O | 2.23 | 11.48 |
| Ti | 8.45 | 14.54 |
| Ni | 18.92 | 26.57 |
| Zr | 11.31 | 10.22 |
| Sn | 42.54 | 29.54 |
| Hf | 16.55 | 7.64 |
| Total | 100.00 | |

From Table 1, it is shown that the composite material of complex alloy includes the element O, so the presence of an oxide can be deduced.

Thus, the parts represented in white in FIG. 5 are further analyzed with the SEM-EDX analysis, and the result is illustrated in Table 2.

TABLE 2

| Element | Weight % | Atomic % |
|---|---|---|
| O | 14.95 | 62.65 |
| Ti | 1.61 | 2.25 |
| Zr | 7.64 | 5.62 |
| Sn | 5.32 | 3.00 |
| Hf | 70.48 | 26.48 |
| Total | 100.00 | |

From Table 2, it is clear that the parts (shown in white) as the heter-material that are represented in FIG. 5 are indeed an oxide.

In summary, the present invention forms the compound with low thermal conductivity in the base material of thermoelectric material by using the method of forming the composite material to reduce the overall thermal conductivity. If composite material of the present invention is applied in the thermoelectric module, the thermoelectric property and the thermoelectric converting efficiency can be enhanced to increase the applications in the industry and benefit in waste heat recycling power generation.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A composite material of a complex alloy, being a Ceramic-Metal Composite based on a thermoelectric material filled with a ceramic material, and represented by the following general formula (I):
A₁₋ₓBₓ (I)
wherein 0.05≦X≦0.2; A represents a Half-Heusler thermoelectric material, and B represents at least one element selected from a group of C, O, and N; and
a proportional composition of A is represented by the following general formula (II):
(Tiₐ₁Zr_{b1}Hf_{c1})_{1-y-z}Ni_{y} Sn_{z} (II)
wherein 0<a1<1, 0<b1<1, 0<c1<1, a1+b1+c1=1, 0.25≧y≦0.35, and 0.25≦z≦0.35.

2. The composite material of the complex alloy as claimed in claim 1, wherein A is an alloy having a crystal structure of a MgAgAs type, and a portion of Ti, Zr, and Hf can be independently substituted by at least one element selected from a group consisting of Nb, Sc, Y, W, Ta, V, La, and Ce.

3. The composite material of the complex alloy as claimed in claim 1, wherein a portion of Ni can be substituted by at least one element selected from a group consisting of Pd, Pt, Co, and Ag.

4. The composite material of the complex alloy as claimed in claim 1, wherein a portion of Sn is substituted by at least one element selected from a group consisting of Sb, Te, Si, Pb, and Ge.

5. The composite material of the complex alloy as claimed in claim 1, wherein a raw material of the B is at least one material selected from a material group consisting of oxide, nitride, carbide, and a combination thereof.

6. The composite material of the complex alloy as claimed in claim 5, wherein the oxide comprises aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide.

7. The composite material of the complex alloy as claimed in claim 5, wherein the nitride comprises boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride.

8. The composite material of the complex alloy as claimed in claim 5, wherein the carbide comprises boron carbide, zirconium carbide, titanium carbide, silicon carbide, niobium carbide, hafnium carbide, wolfram carbide, molybdenum carbide, chromium carbide, or vanadium carbide.

9. A thermoelectric device, comprising an N-type semiconductor and/or a P-type semiconductor, wherein a material of the N-type semiconductor and/or the P-type semiconductor is the composite material of the complex alloy as claimed in claim 1.

10. A thermoelectric module, comprising a plurality of N-type semiconductors and a plurality of P-type semiconductors, wherein the plurality of N-type semiconductors and the plurality of P-type semiconductors are alternately connected in series and coupled through the electrodes therein, and a material of the plurality of N-type semiconductors and/or the plurality of P-type semiconductors is a composite material of a complex alloy as claimed in claim 1.

11. The thermoelectric module as claimed in claim 10, wherein the thermoelectric module is a refrigeration module.

12. A method of generating the composite material of the complex alloy as claimed in claim 1, comprising:
cleaning a plurality of metal raw materials with a purity higher than 99%, wherein the plurality of metal raw materials comprises Ti, Zr, Hf, Ni, and Sn; and
performing a high temperature process with a plurality of heter-raw materials so as to form a thermoelectric composite material having a heter-material.

13. The method of generating the composite material of the complex alloy as claimed in claim 12, wherein the high temperature process comprises sintering or grinding or melting process.

14. The method of generating the composite material of the complex alloy as claimed in claim 12, wherein a temperature of the high temperature process is higher than 750° C.

15. The method of generating the composite material of the complex alloy as claimed in claim 12, wherein a portion of Ti, Zr, and Hf is independently substituted by at least one element selected from a group consisting of Nb, Sc, Y, W, Ta, V, La, and Ce.

16. The method of generating the composite material of the complex alloy as claimed in claim 12, wherein a portion of Ni is substituted by at least one element selected from a group consisting of Pd, Pt, Co, and Ag.

17. The method of generating the composite material of the complex alloy as claimed in claim 12, wherein a portion of Sn is substituted by at least one element selected from a group consisting of Sb, Te, Si, Pb, and Ge.

18. The method of generating the composite material of the complex alloy as claimed in claim 12, wherein the heter-material is at least one material selected from a group consisting of oxide, nitride, carbide, and a combination thereof.

19. The method of generating the composite material of the complex alloy as claimed in claim 18, wherein the oxide in the heter-material comprises aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide.

20. The method of generating the composite material of the complex alloy as claimed in claim 18, wherein the nitride in the heter-material comprises boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride.

21. The method of generating the composite material of the complex alloy as claimed in claim 18, wherein the carbide in the heter-material comprises boron carbide, zirconium carbide, titanium carbide, silicon carbide, niobium carbide, hafnium carbide, wolfram carbide, molybdenum carbide, chromium carbide, or vanadium carbide.

22. The method of generating the composite material of the complex alloy as claimed in claim 12, wherein
before the step of performing the high temperature process further comprises compounding the plurality of metal raw materials according to a predetermined proportion, and
the step of performing the high temperature process comprises melting the plurality of metal raw materials under an atmosphere of the plurality of heter-raw materials for forming a melted product.

23. The method of generating the composite material of the complex alloy as claimed in claim 22, wherein the plurality of heter-raw materials is at least one gas selected from a gas group consisting of oxygen (O), nitrogen (N), and carbon (C).

24. The method of generating the composite material of the complex alloy as claimed in claim 23, wherein the atmosphere comprises oxygen or nitrogen.

25. The method of generating the composite material of the complex alloy as claimed in claim 22, wherein after the step of performing the high temperature process, further comprises cooling the melted product rapidly.

26. The method of generating the composite material of the complex alloy as claimed in claim 25, wherein a cooling speed of the rapid cooling of the melted product is greater than 100° C./sec.

27. The method of generating the composite material of the complex alloy as claimed in claim 25, wherein after cooling the melted product rapidly, further comprises molding, sintering and grinding the thermoelectric composite material having the heter-material.

28. The method of generating the composite material of the complex alloy as claimed in claim 27, wherein a method of molding comprises an injection molding.

29. The method of generating the composite material of the complex alloy as claimed in claim 27, wherein a method of molding and sintering comprises a hot pressing, a hot isotropic pressing, or a spark plasma sintering method.

30. The method of generating the composite material of the complex alloy as claimed in claim 22, wherein after cooling the melted product rapidly, further comprises performing a vacuum annealing thermal treatment to the thermoelectric composite material.

31. The method of generating the composite material of the complex alloy as claimed in claim 30, wherein a temperature of the vacuum annealing thermal treatment is between 750° C. and 1200° C.

32. The method of generating a composite material of a complex alloy as claimed in claim 12, wherein before the step of performing the high temperature process, further comprises compounding the plurality of metal raw materials and the heter-raw material according to a predetermined proportion, wherein the heter-raw material is at least one material selected from a material group consisting of oxide, nitride, carbide, and a combination thereof.

33. The method of generating the composite material of the complex alloy as claimed in claim 32, wherein
the step of performing the high temperature process comprises melting the plurality of metal raw materials and the plurality of heter-raw materials to obtain a melted product, and
after the step of performing the high temperature process, further comprises cooling the melted product rapidly.

34. The method of generating the composite material of the complex alloy as claimed in claim 33, wherein a cooling speed of the cooling step is greater than 100° C./sec.

35. The method of generating the composite material of the complex alloy as claimed in claim 33, wherein after performing the cooling step, further comprises molding, sintering and grinding the thermoelectric composite material having the heter-material.

36. The method of generating the composite material of the complex alloy as claimed in claim 35, wherein a method of molding comprises an injection molding.

37. The method of generating the composite material of the complex alloy as claimed in claim 35, wherein a method of molding and sintering comprises a hot pressing, a hot isotropic pressing, or a spark plasma sintering method.

38. The method of generating the composite material of the complex alloy as claimed in claim 33, wherein after the step of cooling, further comprises performing a vacuum annealing thermal treatment to the thermoelectric composite material.

39. The method of generating the composite material of the complex alloy as claimed in claim 38, wherein a temperature of the vacuum annealing thermal treatment is between 750° C. and 1200° C.

40. The method of generating the composite material of the complex alloy as claimed in claim 32, wherein the oxide in the heter-raw materials comprises aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide.

41. The method of generating the composite material of the complex alloy as claimed in claim 32, wherein the nitride in the heter-raw materials comprises boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride.

42. The method of generating the composite material of the complex alloy as claimed in claim 32, wherein the carbide in the heter-raw materials comprises boron carbide, zirconium carbide, titanium carbide, silicon carbide, niobium carbide, hafnium carbide, wolfram carbide, molybdenum carbide, chromium carbide, or vanadium carbide.

43. The method of generating the composite material of a complex alloy as claimed in claim 32, wherein after the step of compounding the plurality of metal raw materials and the heter-raw material, further comprises mixing the plurality of metal raw materials and the heter-raw material uniformly to obtain a mixture.

44. The method of generating the composite material of the complex alloy as claimed in claim 43, wherein a method of mixing the plurality of metal raw materials and the heter-raw material uniformly comprises ball milling, stirring, or roll mixing.

45. The method of generating the composite material of the complex alloy as claimed in claim 12, wherein before the step of performing the high temperature process further comprises:
compounding the plurality of metal raw materials according to a predetermined proportion;
melting the plurality of metal raw materials for forming a melted product;
cooling the melted product rapidly; and
adding the plurality of heter-raw materials while grinding the melted product to form a mixture.

46. The method of generating the composite material of the complex alloy as claimed in claim 45, wherein the step of performing the high temperature process comprises sintering the mixture.

47. The method of generating the composite material of the complex alloy as claimed in claim 45, wherein after the step of sintering the mixture, further comprises performing a vacuum annealing thermal treatment to the thermoelectric composite material.

48. The method of generating the composite material of the complex alloy as claimed in claim 47, wherein a temperature of the vacuum annealing thermal treatment is between 750° C. and 1200° C.

49. The method of generating the composite material of the complex alloy as claimed in claim 45, wherein the oxide in the heter-raw materials comprises aluminum oxide, zirconium oxide, silicon oxide, titanium oxide, niobium oxide, hafnium oxide, wolfram oxide, lanthanum oxide, vanadium oxide, yttrium oxide, tin oxide, nickel oxide, scandium oxide, tantalum oxide, cerium oxide, indium oxide, antimony oxide, and zinc oxide.

50. The method of generating the composite material of the complex alloy as claimed in claim 45, wherein the nitride in the heter-raw materials comprises boron nitride, zirconium nitride, indium nitride, titanium nitride, aluminum nitride, silicon nitride, niobium nitride, hafnium nitride, wolfram nitride, vanadium nitride, yttrium nitride, nickel nitride, scandium nitride, or tantalum nitride.

51. The method of generating the composite material of the complex alloy as claimed in claim 45, wherein the carbide in the heter-raw materials comprises boron carbide, zirconium carbide, titanium carbide, silicon carbide, niobium carbide, hafnium carbide, wolfram carbide, molybdenum carbide, chromium carbide, or vanadium carbide.
